(19) United States
(12) Patent Application Publication
(10) Pub. No.: US 2018/0092341 A1
(43) Pub. Date: Apr. 5, 2018

(54) UNDERWATER ULTRAVIOLET LIGHT SOURCE

(71) Applicant: John Richard Martin, Santa Clara, CA (US)

(72) Inventor: John Richard Martin, Santa Clara, CA (US)

(21) Appl. No.: 15/284,860

(22) Filed: Oct. 4, 2016

(51) Int. Cl. A01K 85/01; F21L 4/00; F21V 31/00; F21V 23/06; F21V 33/00; F21V 23/00; F21V 21/08; H01L 33/62

(52) U.S. Cl. CPC A01K 85/01; F21L 4/00; F21V 31/00; F21V 23/06; F21Y 2115/10; F21V 23/001; F21V 21/0808; H01L 33/62; F21V 33/008

(57) ABSTRACT

An underwater, self-sticking, artificial ultraviolet light source used to aid in the catching of fish is disclosed.

### CROSS-REFERENCE TO RELATED APPLICATIONS

This application claims the benefit of and priority to the following U.S. Provisional Patent Application No. 62/285,127 filed Oct. 19, 2015 which is incorporated herein by reference in its entirety.

### TECHNICAL FIELD OF THE INVENTION

The invention relates generally to an underwater ultraviolet light source and specifically to a disposable, self-sticking underwater ultraviolet light source used to attract fish and aid in recreational or commercial fishing. The invention has features that allow for extremely long shelf life, is easily activated and is low-cost. The invention describes and enables methods of easily attaching the underwater ultraviolet light source to artificial lures to increase the visibility of the lure to fish. Additionally, the invention describes and enables methods of using the underwater ultraviolet light source to increase the visibility of natural bait.

### BACKGROUND OF THE INVENTION

The typical recreational fisherman will charter a boat, join an excursion on a party-boat or fish from the shoreline. Often a significant investment is made in the fishing trip. A person will often take a day off from work in order to avoid the crowds, pay $100 to $200 for a party boat excursion (more for a chartered boat), rent tackle, buy bait, etc. An avid fisherman who owns his/her own boat and tackle still makes a significant investment in a fishing trip for fuel, time away from work, etc. Many times, the person will come home from a fishing trip with very few fish or no fish at all. While it may be true that a bad day at fishing is better than a good day at work, most people would like to be successful at catching fish on their fishing trip. Most people would be more than willing to spend a little extra money for a device that would increase their chances of catching fish and making their fishing trip more enjoyable and exciting.

Fishing from a boat often means fishing in deeper water where the fish concentrate. Unfortunately, the deeper water has a tendency to block the natural ultraviolet light from the sun. Fish use ultraviolet light reflection to locate their prey. For this reason, many artificial lures are made of materials and are colored to reflect more of the natural ultraviolet light underwater. The more ultraviolet light a lure or bait reflects, the more readily it is seen by a fish. Therefore, there is a need for creating an artificial ultraviolet light source near the bait or lure in order to make it more visible to fish. It would be advantageous if the ultraviolet light source was easily attached to someone's favorite lure and could be used with natural bait if desired. The invention described herein solves the problem of low natural ultraviolet light underwater with a low-cost, simple to use artificial ultraviolet light source.

### BRIEF SUMMARY OF THE INVENTION

The invention described below creates a self-sticking artificial ultraviolet light source using only two electrical components. The discharge rate while the unit is in its package before being activated is as low as the self-discharge rate of the battery. A battery is chosen that has a useful shelf life of several years. The invention is waterproof and can be used in either fresh or salt water. The artificial ultraviolet light source is easily activated once removed from the packaging.

### BRIEF DESCRIPTION OF THE DRAWINGS

FIG. 1 illustrates a side view of artificial ultraviolet light source, showing the hidden components of the artificial ultraviolet light source.

FIG. 2 illustrates a schematic of the artificial ultraviolet light source.

FIG. 3 illustrates an alternative embodiment of the invention with the artificial ultraviolet light source contained in a leader assembly.

### DETAILED DESCRIPTION

An embodiment of an artificial ultraviolet light source is described. In the following description, numerous specific details are set forth. However, it is understood that embodiments may be practiced without these specific details. In other instances, well-known circuits, structures, and techniques have not been shown in detail in order not to obscure the understanding of this description.

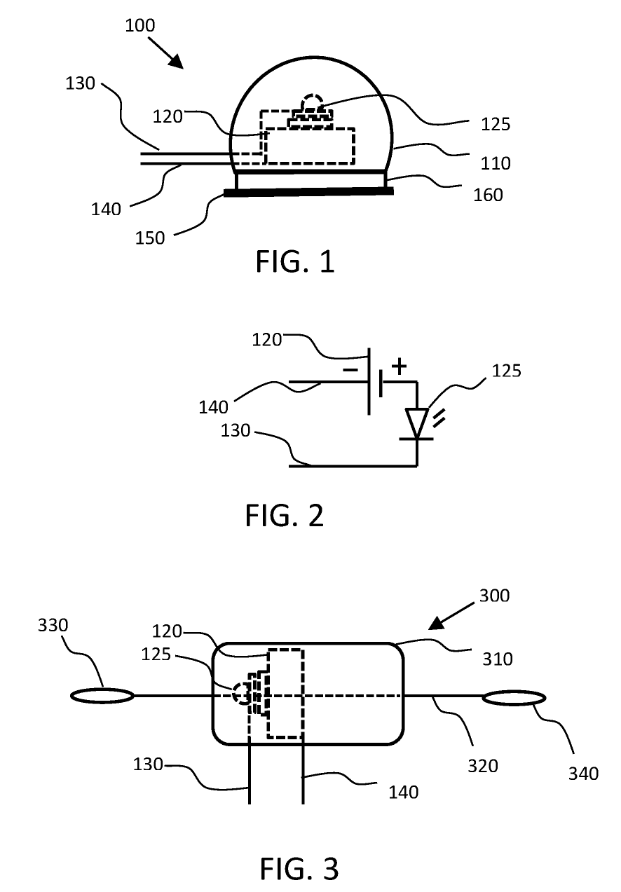

Referring to FIG. 1, which illustrates a side view of artificial ultraviolet light source, showing the internal components of the artificial ultraviolet light source, the main components of the invention can be seen. In the preferred embodiment of the invention, the artificial ultraviolet light source 100 comprises a battery 120 attached to an ultraviolet light LED (Light Emitting Diode) 125, two wires 130 and 140 connecting the LED and battery, double-sided sticky tape 160, translucent encapsulation material 110 and peel-and-stick covering 150 to protect one side of the double-sided sticky tape 160.

In the preferred embodiment of the invention, the battery 120 is a CR1220 coin type manganese lithium battery having a nominal voltage between 3.0 and 3.4 volts and the LED 125 is a light emitting diode that emits light in the 315-400 nm Wave Length of Light (UV A Spectrum) and has a forward voltage drop of approximately 3.0 volts. The combined capacity of the battery 120 and the forward voltage drop of the LED 125 will give the artificial ultraviolet light source 100 a useful operating life of several hours. In other embodiments of the invention, different battery and LED voltages can be used while remaining in the spirit and scope of the invention

The battery 120 attached to an ultraviolet light LED (Light Emitting Diode) 125 with the two wires 130 and 140 used to complete the circuit are encapsulated in an epoxy type material 110 that will allow the ultraviolet light to pass through. The two wires 130 and 140 connecting the LED and battery extend out of the encapsulation material 110 and are used to complete the circuit and activate the artificial ultraviolet light source 100 just before it is used. In the preferred embodiment of the invention, the two wires 130 and 140 are plated wires that have to be twisted together before sticking the artificial ultraviolet light source 100 to a lure or other part of the fishing tackle. In other embodiments of the invention, the two wires 130 and 140 are spring loaded contacts that are separated by a piece of insulation material while in the package. Removing the insulation material will complete the circuit by connecting wires 130 and 140 together. Other methods of completing the circuit, such as spring steel wires bent in opposite directions that could be hooked together have been contemplated.

Typically, the artificial ultraviolet light source 100 would be removed from its packaging, the two wires 130 and 140 would be twisted together, the peel-and-stick covering 150 would be removed and the artificial ultraviolet light source 100 would be pressed onto a lure.

Alternatively, as shown in FIG. 3, an artificial ultraviolet light source 300 could be encapsulated 310 along with leader material 320. Often, a leader is part of the fishing tackle that is used with live bait or natural or artificial bait. A hook with the attached bait would be put on the leader loop 330 while the fishing line from the fishing pole would be attached to leader loop 340. After activating the artificial ultraviolet light source 300 by twisting the two wires 130 and 140 together the LED 125 would shine artificial ultraviolet light on the bait, making the bait more visible to fish.

FIG. 2 shows the schematic of the artificial ultraviolet light source 100 and artificial ultraviolet light source 300. The circuit contains the minimum number of components by careful selection of the battery 120 and LED 125. When the two wires 130 and 140 are be twisted together, current will pass through the LED 125 by slowly discharging the battery 120. Since the nominal forward voltage drop of the LED 125 is roughly equal to the nominal battery 120 voltage, no current limiting resistor is needed in the circuit. In other embodiments of the invention, different battery voltages and LED forward voltage drop values can be used. In such instances, a current limiting resistor may be used to control the discharge rate of the battery in the circuit.

The connections shown in FIG. 2 can be made by soldering the components together, using conductive epoxy, tack welding component leads, etc. Combinations of the aforementioned electrical connection means could also be used.

In view of the wide variety of permutations to the embodiments described herein, this detailed description is intended to be illustrative only, and should not be taken as limiting the scope of the invention. To illustrate, while operations have generally been described with reference to disposable, one-time use devices, embodiments are not so limited. For example, in an embodiment, the LED of the artificial ultraviolet light source can be powered by a rechargeable battery, which would make the device reusable. A relatively large value resistor would be connected in parallel with the diode to allow trickle charging of the internal battery, without shunting much current around the diode during use. In another embodiment, the LED of the artificial ultraviolet light source can be powered by a large value capacitor. Therefore, the specification and drawings are to be regarded in an illustrative rather than a restrictive sense.

1. An underwater ultra violet (“UV”) light source comprising:
a translucent encapsulation material;
internal components disposed within the translucent encapsulation material, the internal components consisting of:
a battery; and
a UV light emitting diode configured to emit light in a subset of ultraviolet spectrum including a range from 315 nm to 400 nm;
two external wire connectors extending from the internal components external to the translucent encapsulation material, the two external wire connectors connected to the UV light emitting diode and the battery; and
an essentially flat, sticky surface for adherence to an external surface of a lure, at least one sticky surface coupled to a surface of a waterproofing encapsulation material as the translucent encapsulation material,
wherein the UV light emitting diode is configured to apply the light via water adjacent to the external surface of the lure to reflect the light from the external surface of the lure into the water.

2. The invention in claim 1 wherein said two external wire connectors are stainless steel wires bent in opposite directions facilitating easy hooking of the two wires in order to establish an electrical connection between said battery and said light emitting diode.

3. The invention in claim 1 wherein said two external wire connectors are formed from softer metals, such as plated copper wires, facilitating easy twisting of the two wires in order to establish an electrical connection between said battery and said light emitting diode.

4. The invention in claim 1 wherein said two external wire connectors are formed to comprise:
spring loaded contacts; and
an insulation material disposed between to separate the spring loaded contacts,
wherein the spring loaded contacts complete a circuit when removed.

5. An underwater ultra violet light source comprising:
a translucent encapsulation material;
internal components disposed within the translucent encapsulation material, the internal components comprising:
a battery; and
an ultraviolet (“UV”) light emitting diode configured to emit light in a subset of ultraviolet spectrum;
two wire connectors configured to connect the UV light emitting diode and the battery; and
leader material extending from each of the two ends of the ultraviolet light source, the leader material comprising:
a first leader loop configured to couple to a first fishing line from a fishing pole and
a second leader loop configured to couple via a second fishing line to bait or a lure,
wherein the ultraviolet (“UV”) light emitting diode is oriented to emit the light linearly in a direction of the second fishing line to apply the light via water adjacent to an external surface of the bait or the lure to reflect the light from the external surface of the bait or the lure into the water,
wherein the translucent encapsulation material is a waterproofing encapsulation material.

6. The invention in claim 5 wherein said two external wire connectors are stainless steel wires bent in opposite directions facilitating easy hooking of the two wires in order to establish an electrical connection between said battery and said light emitting diode.

7. The invention in claim 5 wherein said two external wire connectors are formed from softer metals, such as plated copper wires, facilitating easy twisting of the two wires in order to establish an electrical connection between said battery and said light emitting diode.

8. The invention in claim 5 wherein said light emitting diode emits light in the 315 nm to 400 nm range.

9. An underwater ultra violet (“UV”) light source comprising:
a translucent encapsulation material;
internal components disposed within the translucent encapsulation material, the internal components comprising:
a storage having a first terminal and a second terminal;
a UV light emitting diode having a first terminal and a second terminal, the UV light emitting diode configured to emit light in a subset of ultraviolet spectrum, the first terminal of the storage coupled to the first terminal of the UV light emitting diode; and
two external wire connectors extending from the internal components external to the translucent encapsulation material, one of the two external wire connectors is coupled to the second terminal of the UV light emitting diode and the other of the two external wire connectors is coupled to the second terminal of the battery;
an essentially flat, sticky surface coupled to a surface of the translucent encapsulation material for adherence to an external surface of a lure or bait and a waterproofing encapsulation material,
wherein the UV light emitting diode is configured to apply the light via water adjacent to the external surface of the lure to reflect the light from the external surface of the lure into the water.

10. The invention in claim 9 wherein said two external wire connectors are stainless steel wires bent in opposite directions facilitating easy hooking of the two wires in order to establish an electrical connection between said battery and said light emitting diode.

11. The invention in claim 9 wherein said two external wire connectors are formed from softer metals, such as plated copper wires, facilitating easy twisting of the two wires in order to establish an electrical connection between said battery and said light emitting diode.

12. The invention in claim 9 wherein said light emitting diode emits light in the 315 nm to 400 nm range.

13. The invention in claim 9 wherein said storage comprises:
a battery or a storage capacitor.

14. The invention in claim 9 wherein the UV light emitting diode is configured to apply the light to the lure comprising:
a colored material disposed on the external surface to reflect UV light underwater.

15. The invention in claim 9 wherein the underwater ultraviolet light source is a one-time use device that is disposable.

16. The invention in claim 9 wherein the underwater ultraviolet light source is configured to activate once removed from a packaging.

17. The invention in claim 9 further comprising:
the lure; and
one or more other underwater UV light sources disposed on the surface of the lure to form a system of UV light sources.
